(19) United States
(12) Patent Application Publication
(10) Pub. No.: US 2015/0060646 A1
(43) Pub. Date: Mar. 5, 2015

(54) IMAGE SENSORS AND IMAGE PROCESSING SYSTEMS INCLUDING THE SAME

(71) Applicant: Samsung Electronics Co., Ltd., Suwon-si (KR)

(72) Inventors: Won Ho CHOI, Suwon-si (KR); Jae Jung PARK, Bucheon-si (KR)

(21) Appl. No.: 14/473,069

(22) Filed: Aug. 29, 2014

(30) Foreign Application Priority Data
Sep. 5, 2013 (KR) 10-2013-0106665

(51) Int. Cl. H01L 27/146

(52) U.S. Cl. CPC H01L 27/14643
USPC 250/208.1

(57) ABSTRACT

Image sensors and image processing systems including the image sensors are provided. The image sensors may include a signal transmission circuit including a swing width control circuit configured to control a swing width of a signal using feedback.

### CROSS-REFERENCE TO RELATED APPLICATION

This U.S. non-provisional application claims priority under 35 U.S.C. §119 to Korean Patent Application No. 10-2013-0106665, filed on Sep. 5, 2013, in the Korean Intellectual Property Office, the disclosure of which is hereby incorporated by reference in its entirety.

### BACKGROUND

The present disclosure generally related to the field of electronics and, more particularly, to image sensors.

Image sensors are devices that convert an optical image into an electrical signal. The image sensors may include charge coupled device (CCD) image sensors or complementary metal oxide semiconductor (CMOS) image sensors.

CMOS image sensor chips may include active pixel sensors manufactured using CMOS manufacturing processes. The CMOS image sensor chips may include a pixel array including pixels, which include a photoelectric conversion element converting an optical signal into an electrical signal. The CMOS image sensor chips may also include circuit converting the electrical signal into a digital signal.

As a length of a signal transmission line transmitting a digital signal increases, a transmission speed of the digital signal may decrease due to RC time delay of the signal transmission line. Reducing a swing width of the digital signal may reduce RC time delay of the signal transmission line such that the transmission speed of the digital signal may increase.

### SUMMARY

An image sensor may include a first signal transmission circuit including a first signal transmission line, a first pull-down circuit coupled to the first signal transmission line and a first swing width control circuit coupled to the first pull-down circuit. The first pull-down circuit may be configured to output a first signal in response to a selection signal and first data, the first swing width control circuit may be configured to control a first swing width of the first signal. The image sensor may also include a second signal transmission circuit including a second signal transmission line, a second pull-down circuit coupled to the second signal transmission line and a second swing width control circuit coupled to the second pull-down circuit. The second pull-down circuit may be configured to output a second signal in response to the selection signal and second data that may be complementary to the first data, and the second swing width control circuit may be configured to control a second swing width of the second signal.

According to various embodiments, the image sensor may further include a pixel array including a pixel outputting a pixel signal, an analog-to-digital converter configured to convert the pixel signal into a digital signal, a memory configured to output the first and second data in response to the digital signal, a first amplifier configured to amplify the first signal, a second amplifier configured to amplify the second signal, a differential amplifier configured to amplify a difference between an output signal of the first amplifier and an output signal of the second amplifier and a latch configured to latch an output signal of the differential amplifier in response to a clock signal.

According to various embodiments, the first swing width control circuit may be configured to control the first swing width using negative feedback, and the second swing width control circuit may be configured to control the second swing width using negative feedback.

According to various embodiments, the first signal transmission circuit may include a plurality of first pull-down circuits and a plurality of first swing width control circuits coupled to respective ones of the plurality of first pull-down circuits, and the second signal transmission circuit may include a plurality of second pull-down circuits and a plurality of second swing width control circuits coupled to respective ones of the plurality of second pull-down circuits.

In various embodiments, the plurality of first swing width control circuits may be spaced apart from one another by an equivalent distance, and the plurality of second swing width control circuits may be spaced apart from one another by the equivalent distance.

In various embodiments, the plurality of first swing width control circuits may be spaced apart from one another by different distances, and the plurality of second swing width control circuits may be spaced apart from one another by the different distances.

According to various embodiments, the first swing width control circuit may include a first negative feedback circuit connected to the first signal transmission line and a first bias circuit configured to apply a first bias to the first negative feedback circuit.

In various embodiments, the first negative feedback circuit may include a first pull-up circuit configured to apply an operating voltage to the first signal transmission line in response to a first feedback signal and a first feedback signal generation circuit configured to output the first feedback signal in response to the first signal and the first bias applied by the first bias circuit.

In various embodiments, the second swing width control circuit may include a second negative feedback circuit connected to the second signal transmission line and a second bias circuit configured to apply a second bias to the second negative feedback circuit.

In various embodiments, the second negative feedback circuit may include a second pull-up circuit configured to apply the operating voltage to the second signal transmission line in response to a second feedback signal and a second feedback signal generation circuit configured to output the second feedback signal in response to the second signal and the second bias applied by the second bias circuit.

According to various embodiments, the first swing width may be less than a swing width of the first data.

An image processing system may include an image sensor and a processor configured to process an image data signal output by the image sensor. The image sensor may include a first signal transmission circuit including a first signal transmission line. The first signal transmission circuit may be configured to control a first swing width of a first signal on the first signal transmission line using negative feedback, and the first signal may be generated in response to a selection signal and first data. The image sensor may also include a second signal transmission circuit including a second signal transmission line. The second signal transmission circuit may be configured to control a second swing width of a second signal on the second signal transmission line using negative feedback, and the second signal may be generated in response to the selection signal and second data that may be complementary to the first data.

According to various embodiments, the first signal transmission circuit may include a plurality of first swing width control circuits those may be connected to the first signal transmission line and may be configured to control the first swing width. The second signal transmission circuit may include a plurality of second swing width control circuits those may be connected to the second signal transmission line and may be configured to control the second swing width.

In various embodiments, the plurality of first swing width control circuits may be spaced apart from one another by an equivalent distance, and the plurality of second swing width control circuits may be spaced apart from one another by the equivalent distance.

In various embodiments, the plurality of first swing width control circuits may be configured to buffer the first signal while controlling the first swing width, and the plurality of second swing width control circuits may be configured to buffer the second signal while controlling the second swing width.

According to various embodiments, each of the plurality of first swing width control circuits may include a first pull-up circuit configured to apply an operating voltage to the first signal transmission line in response to a first feedback signal and a first feedback signal generation circuit configured to output the first feedback signal in response to the first signal and a first bias applied by a first bias circuit. Each of the plurality of second swing width control circuits may include a second pull-up circuit configured to apply the operating voltage to the second signal transmission line in response to a second feedback signal and a second feedback signal generation circuit configured to output the second feedback signal in response to the second signal and a second bias applied by a second bias circuit.

An image sensor may include a signal transmission circuit including a pull-down circuit configured to generate a signal in response to image data and a swing width control circuit coupled to an output of the pull-down circuit and configured to control a swing width of the signal to be less than a difference between an operating voltage and a ground voltage of the image sensor.

According to various embodiments, the swing width control circuit may be configured to control the swing width of the signal using negative feedback

According to various embodiments, the swing width control circuit may include a feedback circuit and a bias circuit coupled to the feedback circuit and configured to apply a bias to the feedback circuit.

In various embodiments, the signal transmission circuit may further include a signal transmission line coupled to the pull-down circuit and the swing width control circuit. The feedback circuit may include a pull-up circuit configured to apply the operating voltage VDD to the signal transmission line in response to a feedback signal and a feedback signal generation circuit configured to output the feedback signal in response to the signal and the bias applied by the bias circuit.

In various embodiments, the feedback circuit uses negative feedback to control the swing width of the signal.

According to various embodiments, the pull-down circuit may include one of a plurality of pull-down circuits and the swing width control circuit may include one of a plurality of swing width control circuits arranged in an alternating sequence with the plurality of pull-down circuits.

In various embodiments, the signal transmission circuit may include a first signal transmission circuit, the pull-down circuit may include a first pull-down circuit configured to generate a first signal in response to the image data and the swing width control circuit may include a first swing width control circuit coupled to an output of the first pull-down circuit and configured to control a swing width of the first signal to be less than the difference between the operating voltage and the ground voltage. The signal transmission circuit may further include a second signal transmission circuit including a second pull-down circuit configured to generate a second signal in response to the image data and a second swing width control circuit coupled to an output of the second pull-down circuit and configured to control a swing width of the second signal to be less than the difference between the operating voltage and the ground voltage.

According to various embodiments, image sensor may also include the a first amplifier configured to amplify the first signal, a second amplifier configured to amplify the second signal, a differential amplifier configured to amplify a difference between an output signal of the first amplifier and an output signal of the second amplifier and a latch configured to latch an output signal of the differential amplifier in response to a clock signal.

### BRIEF DESCRIPTION OF THE DRAWINGS

FIG. 1 is a block diagram of an image sensor according to some embodiments of the inventive concept.

FIG. 2 is a block diagram of a data latch block according to some embodiments of the inventive concept.

FIG. 2A is a block diagram of a swing width control circuit according to some embodiments of the inventive concept.

FIG. 3 is a circuit diagram of a data latch block according to some embodiments of the inventive concept.

FIG. 4 is a timing chart of a clock signal and selection signals.

FIG. 5 is a timing chart illustrating operation of a first signal transmission circuit and a second signal transmission circuit according to some embodiments of the inventive concept.

FIG. 6 is a flowchart of a method of operating a data latch block according to some embodiments of the inventive concept.

FIG. 7 is a block diagram of an image processing system including an image sensor according to some embodiments of the inventive concept.

FIG. 8 is a block diagram of an image processing system including an image sensor according to some embodiments of the inventive concept.

### DETAILED DESCRIPTION OF THE EMBODIMENTS

Example embodiments will be described with reference to the accompanying drawings. This invention may, however, be embodied in many different forms and should not be construed as limited to the example embodiments set forth herein. Rather, these example embodiments are provided so that this disclosure will be thorough and complete, and will fully convey the scope of the disclosure to those skilled in the art. Like numbers refer to like elements throughout.

It will be understood that when an element is referred to as being “connected to,” “coupled to” or “adjacent” another element, it can be directly connected to, coupled to or adjacent the other element or intervening elements may be present. In contrast, when an element is referred to as being “directly connected to,” “directly coupled to” or “directly adjacent” another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the example embodiments. As used herein, the singular forms “a”, “an” and “the” are intended to include the plural forms as well, unless the context clearly indicates otherwise. It will be further understood that the terms “comprises,” “comprising,” “includes” or “including” when used in this specification, specify the presence of stated features, regions, steps, operations, elements, and/or components, but do not preclude the presence or addition of one or more other features, regions, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

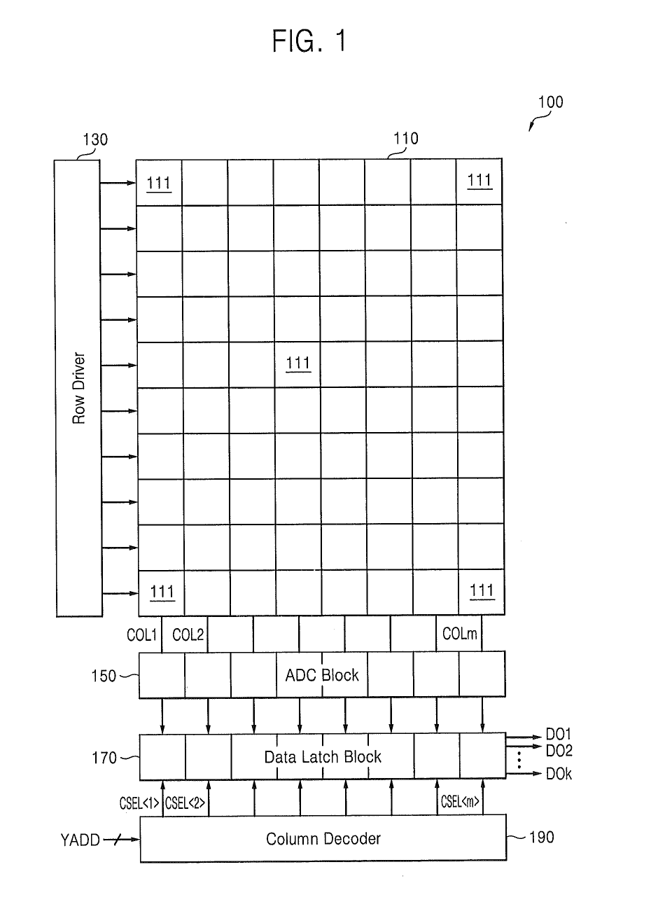

FIG. 1 is a block diagram of an image sensor according to some embodiments of the inventive concept. Referring to FIG. 1, the image sensor 100 may include a pixel array 110, a row driver 130, an analog-to-digital converter (ADC) block 150, a data latch block 170, and a column decoder 190.

The image sensor 100 may be a complementary metal oxide semiconductor (CMOS) image sensor manufactured using CMOS manufacturing processes. The CMOS image sensor may be implemented in various image processing systems. The pixel array 110 may include pixels 111. An analog pixel signal output from each of the pixels 111 may be transmitted to respective columns, COL1 through COLm (where “m” is a natural number). Each of the pixels 111 may include a photoelectric conversion element and a readout circuit that outputs an analog pixel signal based on (e.g., in response to) charges output from the photoelectric conversion element.

The row driver 130 may output control signals to the pixels 111 to control operations of the pixels 111. The ADC block 150 may include analog-to-digital converters (ADCs). Each of the ADCs may perform analog-to-digital conversion on an analog pixel signal output from one of the columns, COL1 through COLm.

The data latch block 170 may latch digital image signals, DO1 through DOk (where “k” is a natural number), generated based on (e.g., in response to) selection signals, CSEL<1> through CSEL<m>, and digital signals output from the ADCs. The column decoder 190 may generate the selection signals, CSEL<1> through CSEL<m>, based on column addresses YADD and may output the selection signals, CSEL<1> through CSEL<m>, to the data latch block 170.

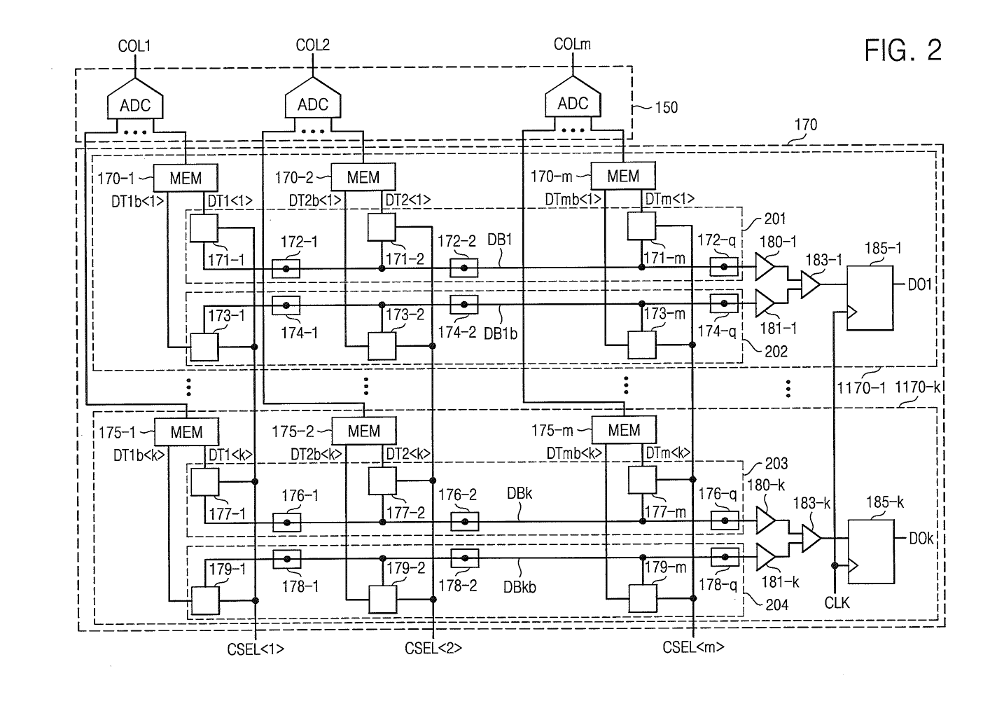

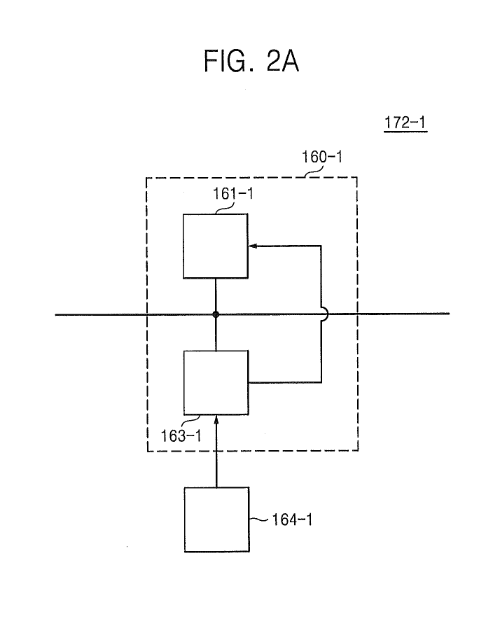

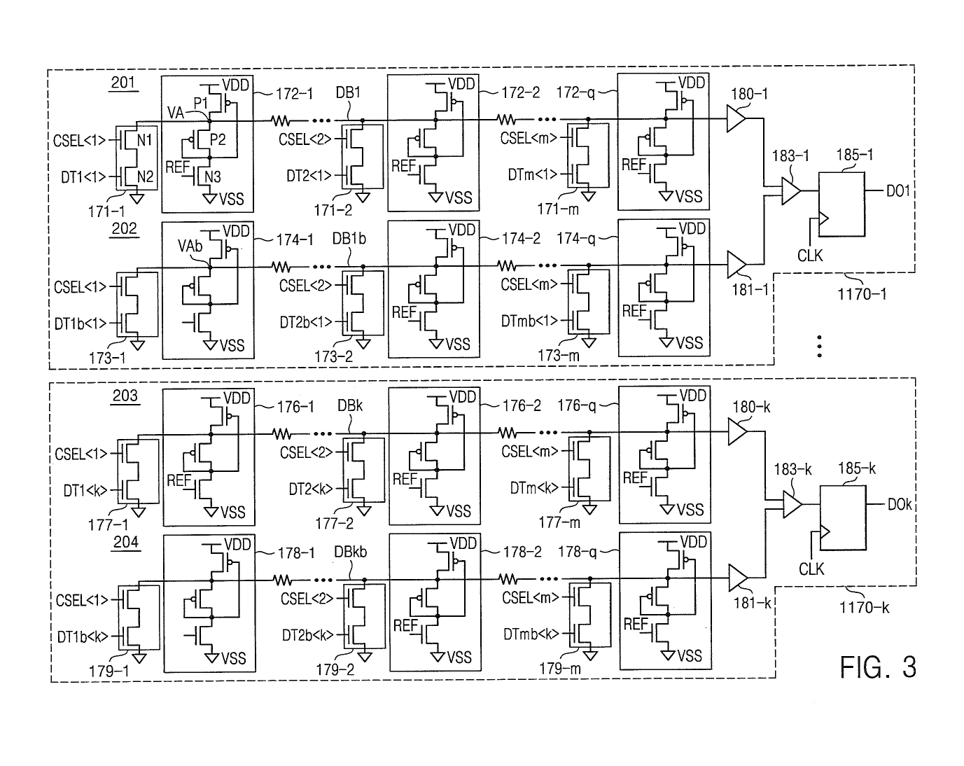

FIG. 2 is a block diagram of a data latch block according to some embodiments of the inventive concept. For convenience in the description, the ADC block 150 is shown together with the data latch block 170. The ADC block 150 may include ADCs and each of the ADCs converts an analog pixel signal output from one of the columns, COL1 through COLm, into a k-bit digital signal. FIG. 2A is a block diagram of a swing width control circuit according to some embodiments of the inventive concept. FIG. 3 is a circuit diagram of a data latch block according to some embodiments of the inventive concept.

Referring to FIGS. 2 and 3, the data latch block 170 may include “k” signal processing circuits, 1170-1 through 1170-k. The first signal processing circuit 1170-1 may process the least significant bit (LSB) of k-bit digital signals. The first signal processing circuit 1170-1 may include memories, 170-1 through 170-m, a first signal transmission circuit 201, a second signal transmission circuit 202, a first amplifier 180-1, a second amplifier 181-1, a differential amplifier 183-1, and a latch 185-1. Each of the first and second signal transmission circuits 201 and 202 may perform function of an asynchronous signal transmission circuit.

Each of the memories, 170-1 through 170-m, may receive and store the first bit (or the first bit value) of a k-bit digital signal output from one of the ADCs. Each of the memories, 170-1 through 170-m, may be a static random access memory (SRAM), a latch, or a flip-flop. Each of the memories, 170-1 through 170-m, may output a corresponding data DT1<1> through DTm<1> and a corresponding complementary data DT1b<1> through DTmb<1>.

The first signal transmission circuit 201 may include a first signal transmission line DB1, first pull-down circuits, 171-1 through 171-m, and first swing width control circuits, 172-1 through 172-q (where “q” is a natural number and equal to or less than m). The first signal transmission line DB1 may be referred to as a data bus.

Each of the first pull-down circuits, 171-1 through 171-m, may determine a level of a first signal VA of the first signal transmission line DB1 based on (e.g., in response to) a corresponding one of the selection signals, CSEL<1> through CSEL<m>, and a corresponding one of the data, DT1<1> through DTm<1>. In some embodiments, each of the first pull-down circuits, 171-1 through 171-m, may include N-channel metal oxide semiconductor (NMOS) transistors N1 and N2 connected in series between the first signal transmission line DB1 and a ground as illustrated in FIG. 3.

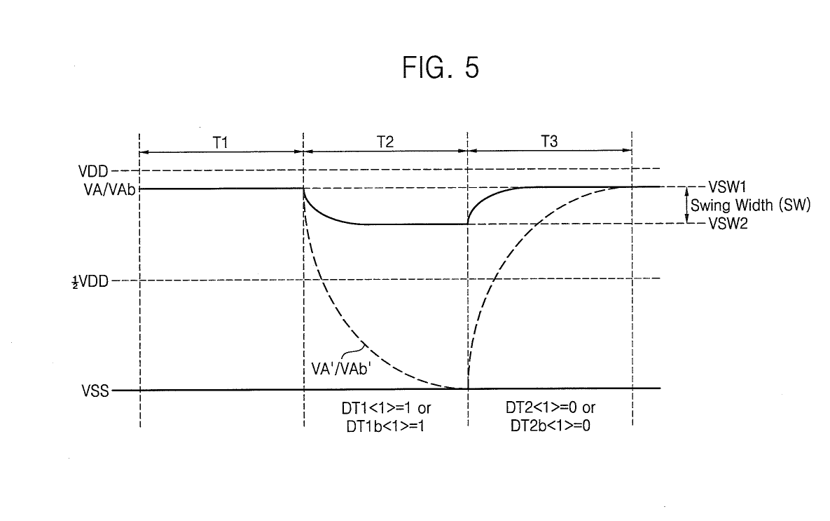

For instance, when the first pull-down circuit 171-1 receives the selection signal CSEL<1> at a high level (or having data “1”) and the data DT1<1> at a high level, as shown in FIG. 5, the level of the first signal VA may be lower than an initial setting level VSW1. In otherwise cases, the level of the first signal VA may be maintained at the initial setting level VSW1. Structures and operations of the first pull-down circuits, 171-2 through 171-m, may be substantially the same as or similar to those of the first pull-down circuit 171-1.

The first swing width control circuits, 172-1 through 172-q, may be connected to the first signal transmission line DB1. The first swing width control circuits, 172-1 through 172-q, may maintain a small and constant swing width of the first signal VA using negative feedback or a negative feedback loop. It will be understood that the first swing width control circuits, 172-1 through 172-q, may control the swing width of the first signal VA to be small and constant.

In some embodiments, a feedback factor or a gain of the negative feedback loop may be 1, but is not limited thereto. The first swing width control circuits, 172-1 through 172-q, may also buffer the first signal VA while maintaining the small and constant swing width (e.g., range) of the first signal VA.

For instance, the swing widths of the data, DT1<1> through DTm<1>, may be determined based on an operating voltage VDD and a ground voltage VSS. In some embodiments, each of the swing widths of the data, DT1<1> through DTm<1> may be a difference between the operating voltage VDD and the ground voltage VSS. Accordingly, the swing width of the first signal VA may be much smaller than each of the swing widths of the data, DT1<1> through DTm<1>, as shown in FIG. 5. For instance, the swing width of the first signal VA may be in a range of about 50 mV to about 200 mV.

Referring to FIG. 2A, in some embodiments, the first swing width control circuit 172-1 may include a first negative feedback circuit 160-1 that is coupled to the first signal transmission line DB1 and a first bias circuit 164-1 that applies a first bias (e.g., a bias voltage or a bias current) to the first negative feedback circuit 160-1. The first negative feedback circuit 160-1 may include a first pull-up circuit 161-1 and a first feedback signal generation circuit 163-1, both of which are coupled to the first signal transmission line DB1. The first feedback signal generation circuit 163-1 may output a first feedback signal in response to the first signal VA and the first bias applied by the first bias circuit 164-1. The first pull-up circuit 161-1 may apply the operating voltage VDD to the first signal transmission line DB1 in response to the first feedback signal.

In some embodiments, the first pull-up circuit 161-1 may be a first P-channel metal oxide semiconductor (PMOS) transistor P1 and the first feedback signal generation circuit 163-1 may be a second PMOS transistor P2 coupled to the first PMOS transistor P1, as illustrated in FIG. 3. The first PMOS transistor P1 may be connected between a power line supplying the operating voltage VDD and the first signal transmission line DB1. The first PMOS transistor P1 may apply the operating voltage VDD to the first signal transmission line DB1 in response to the first feedback signal output provided by the first feedback signal generation circuit 163-1.

The second PMOS transistor P2 may be connected between the first signal transmission line DB1 and the first bias circuit 164-1. The second PMOS transistor P2 may generate the first feedback signal in response to the first signal VA and/or a reference voltage REF. For instance, the second PMOS transistor P2 may be a diode-connected MOS transistor.

The first bias circuit 164-1 may be connected between the second PMOS transistor P2 and the ground VSS and may apply the first bias to the first negative feedback circuit 160-1 in response to the reference voltage REF. In some embodiments, the first bias circuit 164-1 may be an NMOS transistor N3 gated by the reference voltage REF as illustrated in FIG. 3.

Structures and operations of the first swing width control circuits, 172-2 through 172-q, may be substantially the same as or similar to those of the first swing width control circuit 172-1. According to various embodiments, the first swing width control circuits, 172-1 through 172-q, may be spaced apart from one another by an equivalent distance (e.g., an equivalent interval) or by different distances (e.g., different intervals). In other words, distances between two directly adjacent ones of the first swing width control circuits, 172-1 through 172-q, and positions of the first swing width control circuits, 172-1 through 172-q, may vary with design specifications. It will be understood that a “distance” may refer to a physical distance and/or an electrical distance between two directly adjacent ones of the first swing width control circuits, 172-1 through 172-q.

The first amplifier 180-1 may receive and amplify the first signal VA of the first signal transmission line DB1.

The second signal transmission circuit 202 may include a second signal transmission line DB1b, second pull-down circuits, 173-1 through 173-m, and second swing width control circuits, 174-1 through 174-q. The second signal transmission line DB1b may be referred to as a complementary data bus.

Each of the second pull-down circuits, 173-1 through 173-m, may determine a level of a second signal VAb of the second signal transmission line DB1b based on (e.g., in response to) a corresponding one of the selection signals, CSEL<1> through CSEL<m>, and a corresponding one of the complementary data, DT1b<1> through DTmb<1>. In some embodiments, each of the second pull-down circuits, 173-1 through 173-m, may include NMOS transistors connected in series between the second signal transmission line DB1b and the ground as illustrated in FIG.

For instance, when the second pull-down circuit 173-1 receives the selection signal CSEL<1> at the high level and the complementary data DT1b<1> at a high level, as shown in FIG. 5, the level of the second signal VAb may be lower than the initial setting level VSW1. In otherwise cases, the level of the second signal VAb may be maintained at the initial setting level VSW1. Structures and operations of the second pull-down circuits 173-1 through 173-m may be substantially the same as or similar to those of the first pull-down circuit 171-1.

The second swing width control circuits, 174-1 through 174-q, may be connected to the second signal transmission line DB1b. The second swing width control circuits, 174-1 through 174-q, may maintain a small and constant swing width SW of the second signal VAb, as illustrated in FIG. 5, using negative feedback or a negative feedback loop. The second swing width control circuits 174-1 through 174-q may also buffer the second signal VAb while maintaining the small and constant swing width SW of the second signal VAb.

For instance, the swing widths of the complementary data DT1b<1> through DTmb<1> may be determined based on the operating voltage VDD and the ground voltage VSS. In some embodiments, each of the swing widths of the complementary data DT1b<1> through DTmb<1> may be the difference between the operating voltage VDD and the ground voltage VSS. Accordingly, the swing width of the second signal VAb may be much smaller than swing widths of the complementary data DT1b<1> through DTmb<1>, as shown in FIG. 5. The swing width of the second signal VAb may be in a range of about 50 mV to about 200 mV.

Structures and operations of the second swing width control circuits 174-1 through 174-q may be substantially the same as or similar to those of the first swing width control circuit 172-1. According to various embodiments, the second swing width control circuits 174-1 through 174-q may be spaced apart from one another by an equivalent distance or by different distances. In other words, distances between two directly adjacent ones of the second swing width control circuits, 174-1 through 174-q, and positions of the second swing width control circuits, 174-1 through 174-q, may vary with design specifications. In some embodiments, the second swing width control circuits 174-1 through 174-q may be placed corresponding to the first swing width control circuits 172-1 through 172-q, respectively. For instance, the second swing width control circuits 174-1 through 174-q may be spaced apart from one another by a second distance that is substantially the same as or similar to a first distance, by which the first swing width control circuits 172-1 through 172-q are spaced apart from one another.

The second amplifier 181-1 may receive and amplify the second signal VAb of the second signal transmission line DB1b. The differential amplifier 183-1 may amplify a difference between an output signal of the first amplifier 180-1 and an output signal of the second amplifier 181-1. The latch 185-1 may latch an output signal of the differential amplifier 183-1 based on a clock signal CLK. The latch 185-1 may be a D flip-flop.

The k-th signal processing circuit 1170-k may process the most significant bit (MSB) of k-bit digital signals. The k-th signal processing circuit 1170-k may include memories 175-1 through 175-m, a first signal transmission circuit 203, a second signal transmission circuit 204, a first amplifier 180-k, a second amplifier 181-k, a differential amplifier 183-k, and a latch 185-k.

Each of the first and second signal transmission circuits 203 and 204 may perform a function of an asynchronous signal transmission circuit.

Each of the memories 175-1 through 175-m may receive and store the k-th bit (or the k-th bit value) of a k-bit digital signal output from one of the ADCs. Each of the memories 175-1 through 175-m may be an SRAM, a latch, or a flip-flop. The memories 175-1 through 175-m may output a corresponding data DT1<k> through DTm<k> and a corresponding complementary data DT1b<k> through DTmb<k>.

The first signal transmission circuit 203 may include a first signal transmission line DBk, first pull-down circuits 177-1 through 177-m, and first swing width control circuits 176-1 through 176-q. The first signal transmission line DBk may be referred to as a data bus.

Each of the first pull-down circuits 177-1 through 177-m may determine a level of a first signal of the first signal transmission line DBk based on a corresponding one of the selection signals, CSEL<1> through CSEL<m>, and a corresponding one of the data, DT1<k> through DTm<k>. Structures and operations of the first pull-down circuits 177-1 through 177-m may be substantially the same as or similar to those of the first pull-down circuit 171-1.

The first swing width control circuits, 176-1 through 176-q, may be connected to the first signal transmission line DBk. The first swing width control circuits, 176-1 through 176-q, may maintain a small and constant swing width of the first signal of the first signal transmission line DBk using negative feedback or a negative feedback loop. The first swing width control circuits 176-1 through 176-q may also buffer the first signal of the first signal transmission line DBk while maintaining the small and constant swing width of the first signal. It will be understood that the first swing width control circuits, 176-1 through 176-q, may control the swing width of the first signal to be small and constant using negative feedback.

Structures and operations of the first swing width control circuits, 176-1 through 176-q, may be substantially the same as or similar to those of the first swing width control circuit 172-1. According to various embodiments, the first swing width control circuits 176-1 through 176-q may be spaced apart from one another by an equivalent distance or by different distances. In other words, distances between two directly adjacent ones of the first swing width control circuits, 176-1 through 176-q, and positions of the first swing width control circuits, 176-1 through 176-q, may vary with design specifications.

The first amplifier 180-k may receive and amplify the first signal of the first signal transmission line DBk.

The second signal transmission circuit 204 may include a second signal transmission line DBkb, second pull-down circuits, 179-1 through 179-m, and second swing width control circuits, 178-1 through 178-q. The second signal transmission line DBkb may be referred to as a complementary data bus.

Each of the second pull-down circuits 179-1 through 179-m may determine a level of a second signal of the second signal transmission line DBkb based on a corresponding one of the selection signals, CSEL<1> through CSEL<m>, and a corresponding one of the complementary data, DT1b<k> through DTmb<k>. Structures and operations of the second pull-down circuits 179-1 through 179-m may be substantially the same as or similar to those of the first pull-down circuit 171-1.

The second swing width control circuits 178-1 through 178-q may be connected to the second signal transmission line DBkb. The second swing width control circuits 178-1 through 178-q may maintain a small and constant swing width of the second signal of the second signal transmission line DBkb using negative feedback or a negative feedback loop. The second swing width control circuits 178-1 through 178-q may also buffer the second signal of the second signal transmission line DBkb while maintaining the small and constant swing width of the second signal.

Structures and operations of the second swing width control circuits 178-1 through 178-q may be substantially the same as or similar to those of the first swing width control circuit 172-1. According to various embodiments, the second swing width control circuits 178-1 through 178-q may be spaced apart from one another by an equivalent distance or by different distances. In other words, distances between two directly adjacent ones of the second swing width control circuits, 178-1 through 178-q, and positions of the second swing width control circuits, 178-1 through 178-q, may vary with design specifications. For instance, the second swing width control circuits 178-1 through 178-q may be placed corresponding to the first swing width control circuits 176-1 through 176-q, respectively.

The second amplifier 181-k may receive and amplify the second signal of the second signal transmission line DBkb. The differential amplifier 183-k may amplify a difference between an output signal of the first amplifier 180-k and an output signal of the second amplifier 181-k. The latch 185-k may latch an output signal of the differential amplifier 183-k based on the clock signal CLK. The latch 185-k may be a D flip-flop.

As described above, a data line transmitting a first signal related with data is referred to as a first signal transmission line and a circuit including the first signal transmission line is referred to as a first signal transmission circuit. In addition, a data line transmitting a second signal related with complementary data is referred to as a second signal transmission line and a circuit including the second signal transmission line is referred to as a second signal transmission circuit.

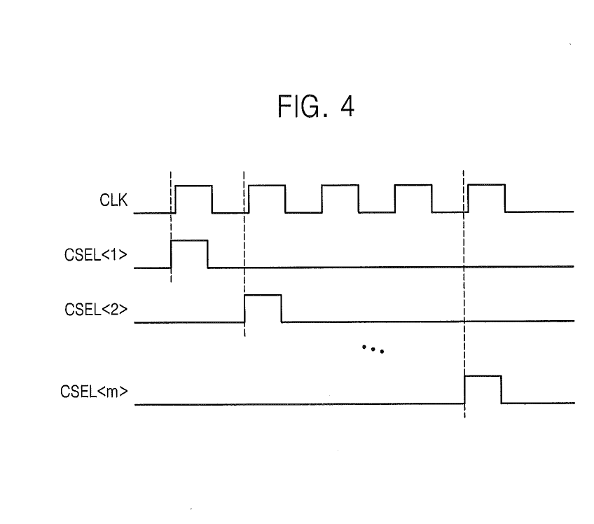

FIG. 4 is a timing chart of a clock signal and selection signals. The column decoder 190 may sequentially generate the selection signals CSEL<1> through CSEL<m>, which do not overlap one another, in response to the column addresses YADD.

Referring to FIGS. 3 and 4, when the first selection signal CSEL<1> is at the high level, a level of the first signal of each of the first signal transmission lines DB1 through DBk may be determined according to a level of a corresponding one of the data DT1<1> through DT1<k>. In addition, when the first selection signal CSEL<1> is at the high level, a level of the second signal of each of the second signal transmission lines DB1b through DBkb may be determined according to a level of a corresponding one of the complementary data DT1b<1> through DT1b<k>.

Each of the first amplifiers 180-1 through 180-k may amplify the level of the first signal of a corresponding one of the first signal transmission lines DB1 through DBk. Each of the second amplifiers 181-1 through 181-k may amplify the level of the second signal of a corresponding one of the second signal transmission lines DB1b through DBkb. Each of the differential amplifiers 183-1 through 183-k may amplify a difference between an output signal of a corresponding one of the first amplifiers 180-1 through 180-k and an output signal of a corresponding one of the second amplifiers 181-1 through 181-k.

Each of the latches 185-1 through 185-k may latch an output signal of a corresponding one of the differential amplifiers 183-1 through 183-k as one of the digital image signals DO1 through DOk in response to a first rising edge of the clock signal CLK. Accordingly, the data latch block 170 may output the “k” digital image signals DO1 through DOk together corresponding to an analog pixel signal output through the first column COL1.

When the second selection signal CSEL<2> is at the high level, a level of the first signal of each of the first signal transmission lines DB1 through DBk may be determined according to a level of a corresponding one of the data DT2<1> through DT2<k>. In addition, when the second selection signal CSEL<2> is at the high level, the level of a second signal of each of the second signal transmission lines DB1b through DBkb may be determined according to a level of a corresponding one of the complementary data DT2b<1> through DT2b<k>.

Each of the first amplifiers 180-1 through 180-k may amplify the level of the first signal of a corresponding one of the first signal transmission lines DB1 through DBk. Each of the second amplifiers 181-1 through 181-k may amplify the level of the second signal of a corresponding one of the second signal transmission lines DB1b through DBkb. Each of the differential amplifiers 183-1 through 183-k may amplify a difference between the output signal of a corresponding one of the first amplifiers 180-1 through 180-k and the output signal of a corresponding one of the second amplifiers 181-1 through 181-k.

Each of the latches 185-1 through 185-k may latch an output signal of a corresponding one of the differential amplifiers 183-1 through 183-k as one of the digital image signals DO1 through DOk in response to a second rising edge of the clock signal CLK. Accordingly, the data latch block 170 may output the “k” digital image signals DO1 through DOk together corresponding to a pixel signal output through the second column COL2.

When the m-th selection signal CSEL<m> is at the high level, a level of the first signal of each of the first signal transmission lines DB1 through DBk may be determined according to a level of a corresponding one of the data DTm<1> through DTm<k>. In addition, when the m-th selection signal CSEL<m> is at the high level, a level of the second signal of each of the second signal transmission lines DB1b through DBkb may be determined according to a level of a corresponding one of the complementary data DTmb<1> through DTmb<k>.

Each of the first amplifiers 180-1 through 180-k may amplify the level of the first signal of a corresponding one of the first signal transmission lines DB1 through DBk. Each of the second amplifiers 181-1 through 181-k may amplify the level of the second signal of a corresponding one of the second signal transmission lines DB1b through DBkb. Each of the differential amplifiers 183-1 through 183-k may amplify a difference between an output signal of a corresponding one of the first amplifiers 180-1 through 180-k and an output signal of a corresponding one of the second amplifiers 181-1 through 181-k.

Each of the latches 185-1 through 185-k may latch an output signal of a corresponding one of the differential amplifiers 183-1 through 183-k as one of the digital image signals DO1 through DOk in response to an m-th rising edge of the clock signal CLK. Accordingly, the data latch block 170 may output the “k” digital image signals DO1 through DOk together corresponding to a pixel signal output through the m-th column CQLm.

FIG. 5 is a timing chart illustrating operation of a first signal transmission circuit and a second signal transmission circuit according to some embodiments of the inventive concept. Operations of the first signal transmission circuit 201 will be described.

A first period T1 may be an initialization period. A second period T2 shows a level of the first signal VA of the first signal transmission line DB1 when only the first selection signal CSEL<1> is at the high level and the data DT1<1> is at the high level. A third period T3 shows a level of the first signal VA of the first signal transmission line DB1 when only the second selection signal CSEL<2> is at the high level and the data DT2<1> is at a low level (e.g., having data “0”).

In the first period T1, the reference voltage REF is applied to a gate of the NMOS transistor N3, and therefore, the NMOS transistor N3 is turned on. Accordingly, the PMOS transistor P1 applies the operating voltage VDD to the first signal transmission line DB1 in response to a feedback signal. As a result, the first signal VA of the first signal transmission line DB1 is maintained at a level lower than the operating voltage VDD. The first signal VA may have a level higher than a half of the operating voltage ½VDD, i.e., the first level VSW1 may be closer to the operating voltage VDD than to the ground voltage VSS.

In the second period T2, only the first pull-down circuit 171-1 is turned on, and therefore, the first level VSW1 of the first signal VA of the first signal transmission line DB1 may be reduced to the second level VSW2 that is determined by the first swing width control circuit 172-1. It will be understood that the swing width SW may be determined based on the first level VSW1 and the second level VSW2. For instance, the swing width SW is a difference between the first level VSW1 and the second level VSW2.

In the third period T3, all of the first pull-down circuits 171-1 through 171-m are turned off, and therefore, the first signal VA of the first signal transmission line DB1 may be increase to the initial level, i.e., the first level VSW1.

In FIG. 5, a reference character VA′ denotes a first signal of the first signal transmission line DB1 when the first signal transmission circuit 201 does not include the first swing width control circuits 172-1 through 172-q. In the second period T2, the first signal VA′ of the first signal transmission line DB1 may be pulled down to the level of the ground voltage VSS. In the third period T3, the first signal VA′ of the first signal transmission line DB1 may increase to the initial level VSW1. In other words, when the first signal transmission circuit 201 does not include the first swing width control circuits 172-1 through 172-q, the swing width of the first signal VA′ of the first signal transmission line DB1 is greater than the swing width of the first signal VA of the first signal transmission line DB1 and thus transmission speed of the first signal VA′ may decrease relative to transmission speed of the first signal VA due to the RC time constant of the first signal transmission line DB1.

However, according to some embodiments of the inventive concept, the first signal transmission circuit 201 may maintain a small swing width of the first signal VA transmitted through the first signal transmission line DB1 using the first swing width control circuits 172-1 through 172-q connected to the first signal transmission line DB1. As a result, the first signal VA may be less influenced by the RC time constant of the first signal transmission line DB1, and therefore, the transmission speed of the first signal VA may increase.

According to FIG. 5, the first period T1 may be the initialization period. The second period T2 shows a level of the second signal VAb of the second signal transmission line DB1b when only the first selection signal CSEL<1> is at the high level and the complementary data DT1b<1> is at the high level. The third period T3 shows a level of the second signal VAb of the second signal transmission line DB1b when only the second selection signal CSEL<2> is at the high level and the complementary data DT2b<1> is at the low level.

In FIG. 5, a reference character VAb′ denotes a second signal of the second signal transmission line DB1b when the second signal transmission circuit 202 does not include the second swing width control circuits 174-1 through 174-q. In the second period T2, the second signal VAb′ of the second signal transmission line DB1b may be pulled down to the level of the ground voltage VSS. In the third period T3, the second signal VAb′ of the second signal transmission line DB1b may increase to the initial level VSW1.

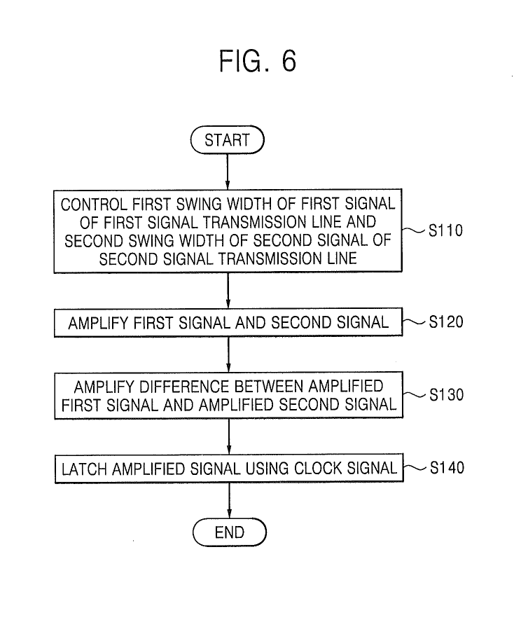

FIG. 6 is a flowchart of a method of operating a data latch block according to some embodiments of the inventive concept. Since structures and operations of the signal processing circuits 1170-1 through 1170-k may be substantially the same as or similar to one another, operations of the first signal processing circuit 1170-1 will be described with reference to FIGS. 1 through 6.

Each of the first swing width control circuits 172-1 through 172-q included in the first signal transmission circuit 201 may control the first swing width of the first signal VA of the first signal transmission line DB1, which is determined according to the corresponding one of the data DT1<1> through DTm<1>, using negative feedback whenever the corresponding one of the selection signals CSEL<1> through CSEL<m> is activated (operation S110).

For instance, when the corresponding one of the data DT1<1> through DTm<1> is at the high level, the first signal VA of the first signal transmission line DB1 may be at the second level VSW2. When the corresponding one of the data DT1<1> through DTm<1> is at the low level, the first signal VA of the first signal transmission line DB1 may be at the first level VSW1.

Each of the second swing width control circuits 174-1 through 174-q included in the second signal transmission circuit 202 may control the second swing width of the second signal VAb of the second signal transmission line DB1b, which is determined according to the corresponding one of the complementary data DT1b<1> through DTmb<1>, using negative feedback when the corresponding one of the selection signals CSEL<1> through CSEL<m> is activated (operation S110).

For instance, when the corresponding one of the complementary data DT1b<1> through DTmb<1> is at the low level, the second signal VAb of the second signal transmission line DB1b may be at the first level VSW1. When the corresponding one of the complementary data DT1b<1> through DTmb<1> is at the high level, the second signal VAb of the second signal transmission line DB1b may be at the second level VSW2. It will be understood that the first signal VA of the first signal transmission line DB1 and the second signal VAb of the second signal transmission line DB1b may be differential signals or complementary signals.

The first amplifier 180-1 may amplify the first signal VA and the second amplifier 181-1 may amplify the second signal VAb (operation S120). The differential amplifier 183-1 may amplify a difference between an output signal of the first amplifier 180-1 and an output signal of the second amplifier 181-1 (operation S130). The latch 185-1 may latch an output signal of the differential amplifier 183-1 as the corresponding signal DO1 based on the clock signal CLK (operation S140).

As described above, the image sensor 100 may include the swing width control circuits 172-1 through 172-q, 174-1 through 174-q, 176-1 through 176-q, and 178-1 through 178-q in order to reduce a delay difference between a signal transmitted from portions far from each of the latches 185-1 through 185-k and a signal transmitted from portions close to each of the latches 185-1 through 185-k.

The swing width control circuits 172-1 through 172-q, 174-1 through 174-q, 176-1 through 176-q, and 178-1 through 178-q having a negative feedback loop may buffer a signal transmitted through a signal transmission line while maintaining a small swing width of the signal.

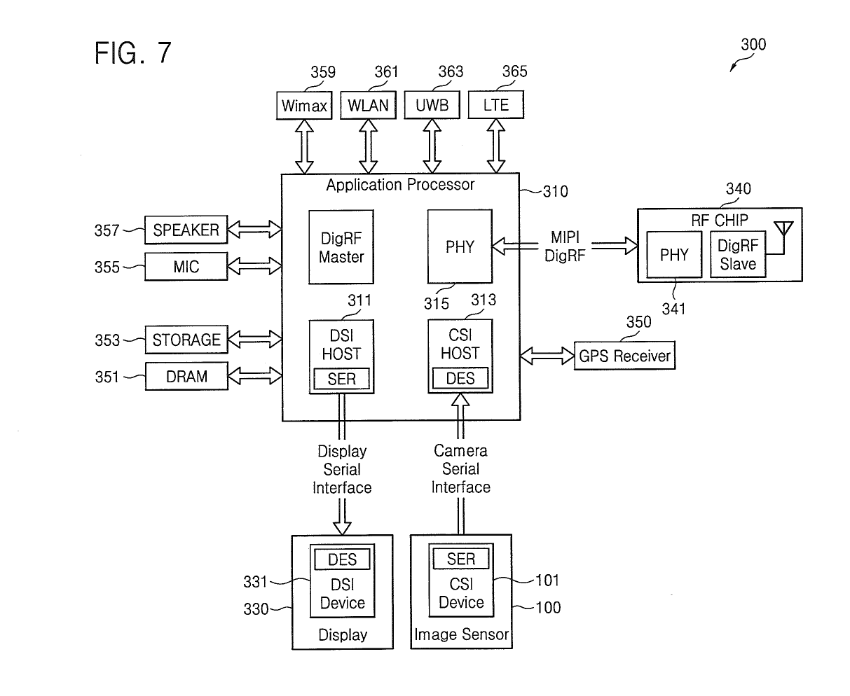

FIG. 7 is a block diagram of an image processing system including an image sensor according to some embodiments of the inventive concept. Referring to FIGS. 1 through 7, the image processing system 300 may be implemented as a portable electronic device which can use or support mobile industry processor interface (MIPI®).

The portable electronic device may be a laptop computer, a personal digital assistant (PDA), a portable media player (PMP), a mobile phone, a smart phone, a tablet personal computer (PC), a mobile internet device (MID), a wearable computer, an internet of things (IoT) device, an internet of everything (IoE) device, a digital camera, or a camcorder.

The image processing system 300 may include an application processor 310, an image sensor 100, and a display 330.

A camera serial interface (CSI) host 313 implemented in the application processor 310 may perform serial communication with a CSI device 101 included in the image sensor 100 through CSI. A deserializer DES and a serializer SER may be implemented in the CSI host 313 and the CSI device 101, respectively.

A display serial interface (DSI) host 311 implemented in the application processor 310 may perform serial communication with a DSI device 331 included in the display 330 through DSI. A serializer SER and a deserializer DES may be implemented in the DSI host 311 and the DSI device 331, respectively. The deserializer DES and the serializer SER may process electrical or optical signals.

The image processing system 300 may also include a radio frequency (RF) chip 340 communicating with the application processor 310. A physical layer (PHY) 315 of the application processor 310 and a PHY 341 of the RF chip 340 may communicate data with each other according to MIPI DigRF. The application processor 310 may further include DigRF Master, and the RF chip 340 may further include DigRF Slave.

The image processing system 300 may further include a global positioning system (GPS) receiver 350, a memory 351 such as dynamic random access memory (DRAM), a data storage device 353 implemented by non-volatile memory such as NAND flash-based memory, a microphone (MIC) 355, and a speaker 357.

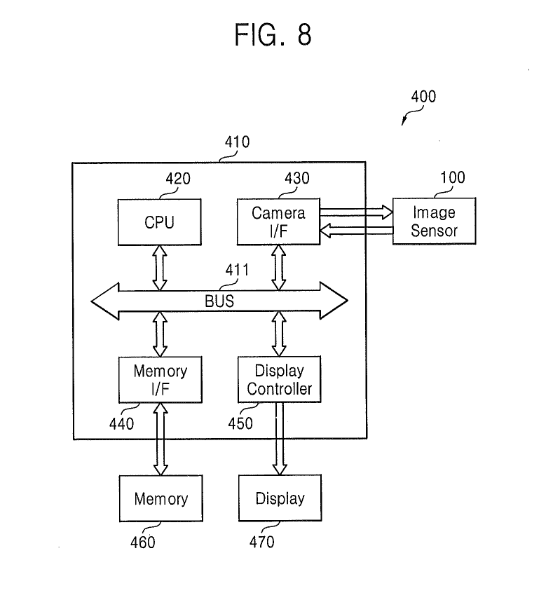

The image processing system 300 may communicate with external devices using at least one communication protocol (or standard) such as a worldwide interoperability for microwave access (Wimax) 359, a wireless local area network (WLAN) 361, an ultra-wideband (UWB) 363, or a long term evolution (LTE) 365. The image processing system 300 may also communicate with external wireless communication devices using Bluetooth or WiFi. In some embodiments, the application processor 310 may also include elements 411, 420, 440, and 450 illustrated in FIG. 8.

FIG. 8 is a block diagram of an image processing system including an image sensor according to some embodiments of the inventive concept. The image processing system 400 illustrated in FIG. 8 may be implemented as a PC or a portable electronic device.

The portable electronic device may be a laptop computer, a PDA, a PMP, a mobile phone, a smart phone, a tablet PC, a MID, an IoT device, an IoE device, a digital camera, or a camcorder.

The image processing system 400 may include an image sensor 100, a processor 410, a memory 460, and a display (or a display device) 470. The image sensor 100 may be included in a camera module. The camera module may include mechanical elements that can control operations of the image sensor 100.

The processor 410 may be implemented as an integrated circuit (IC), a system on chip (SoC), an application processor, or a mobile application processor. The processor 410 may control operations of the image sensor 100, the memory 460, and the display 470. The processor 410 may process image data output from the image sensor 100 and may store the processed image data in the memory 460 or display the processed image data on the display 470.

The processor 410 may include a central processing unit (CPU) 420, a camera interface (I/F) 430, a memory I/F 440, and a display controller 450. The CPU 420 may control operations of the camera I/F 430, the memory I/F 440, and the display controller 450 through a bus 411.

The CPU 420 may be implemented as a multi-core processor or a multi-CPU. According to the control of the CPU 420, the camera I/F 430 may transmit control signals to the image sensor 100 for controlling the image sensor 100 and may transmit image data signals from the image sensor 100 to the CPU 420, the memory I/F 440, and/or the display controller 450.

The memory I/F 440 may interface data between the processor 410 and the memory 460. The display controller 450 may transmit data to be displayed on the display 470 to the display 470.

The memory 460 may be a volatile memory such as DRAM or a flash-based memory. The flash-based memory may be implemented as a multimedia card (MMC), an embedded MMC (eMMC), an embedded solid state drive (eSSD), or a universal flash storage (UFS).

As described above, according to some embodiments of the inventive concept, an image sensor may control a swing width of a signal transmitted through a signal transmission line using negative feedback, thereby reducing a delay difference between a signal transmitted from a portion close to a synchronous circuit connected to the signal transmission line and a signal transmitted from a portion far from the synchronous circuit.

The above-disclosed subject matter is to be considered illustrative, and not restrictive, and the appended claims are intended to cover all such modifications, enhancements, and other embodiments, which fall within the true spirit and scope of the inventive concept. Thus, to the maximum extent allowed by law, the scope is to be determined by the broadest permissible interpretation of the following claims and their equivalents, and shall not be restricted or limited by the foregoing detailed description.

1. An image sensor comprising:
a first signal transmission circuit comprising a first signal transmission line, a first pull-down circuit coupled to the first signal transmission line and a first swing width control circuit coupled to the first pull-down circuit, wherein the first pull-down circuit is configured to output a first signal in response to a selection signal and first data, and wherein the first swing width control circuit is configured to control a first swing width of the first signal; and
a second signal transmission circuit comprising a second signal transmission line, a second pull-down circuit coupled to the second signal transmission line and a second swing width control circuit coupled to the second pull-down circuit, wherein the second pull-down circuit is configured to output a second signal in response to the selection signal and second data that is complementary to the first data, and wherein the second swing width control circuit is configured to control a second swing width of the second signal.

2. The image sensor of claim 1, further comprising:
a pixel array comprising a pixel outputting a pixel signal;
an analog-to-digital converter configured to convert the pixel signal into a digital signal;
a memory configured to output the first and second data in response to the digital signal;
a first amplifier configured to amplify the first signal;
a second amplifier configured to amplify the second signal;
a differential amplifier configured to amplify a difference between an output signal of the first amplifier and an output signal of the second amplifier; and
a latch configured to latch an output signal of the differential amplifier in response to a clock signal.

3. The image sensor of claim 1, wherein the first swing width control circuit is configured to control the first swing width using negative feedback, and the second swing width control circuit is configured to control the second swing width using negative feedback.

4. The image sensor of claim 1, wherein the first signal transmission circuit comprises a plurality of first pull-down circuits and a plurality of first swing width control circuits coupled to respective ones of the plurality of first pull-down circuits, and the second signal transmission circuit comprises a plurality of second pull-down circuits and a plurality of second swing width control circuits coupled to respective ones of the plurality of second pull-down circuits.

5. (canceled)

6. (canceled)

7. The image sensor of claim 1, wherein the first swing width control circuit comprises:
a first negative feedback circuit connected to the first signal transmission line; and
a first bias circuit configured to apply a first bias to the first negative feedback circuit.

8. The image sensor of claim 7, wherein the first negative feedback circuit comprises:
a first pull-up circuit configured to apply an operating voltage to the first signal transmission line in response to a first feedback signal; and
a first feedback signal generation circuit configured to output the first feedback signal in response to the first signal and the first bias applied by the first bias circuit.

9. The image sensor of claim 8, wherein the second swing width control circuit comprises:
a second negative feedback circuit connected to the second signal transmission line; and
a second bias circuit configured to apply a second bias to the second negative feedback circuit.

10. The image sensor of claim 9, wherein the second negative feedback circuit comprises:
a second pull-up circuit configured to apply the operating voltage to the second signal transmission line in response to a second feedback signal; and
a second feedback signal generation circuit configured to output the second feedback signal in response to the second signal and the second bias applied by the second bias circuit.

11. The image sensor of claim 1, wherein the first swing width is less than a swing width of the first data.

12. An image processing system comprising:
an image sensor; and
a processor configured to process an image data signal output by the image sensor,
wherein the image sensor comprises:
a first signal transmission circuit comprising a first signal transmission line, wherein the first signal transmission circuit is configured to control a first swing width of a first signal on the first signal transmission line using negative feedback, and wherein the first signal is generated in response to a selection signal and first data; and
a second signal transmission circuit comprising a second signal transmission line, wherein the second signal transmission circuit is configured to control a second swing width of a second signal on the second signal transmission line using negative feedback, and wherein the second signal is generated in response to the selection signal and second data that is complementary to the first data.

13. The image processing system of claim 12, wherein the first signal transmission circuit comprises a plurality of first swing width control circuits those are connected to the first signal transmission line and are configured to control the first swing width, and
the second signal transmission circuit comprises a plurality of second swing width control circuits those are connected to the second signal transmission line and are configured to control the second swing width.

14. (canceled)

15. (canceled)

16. The image processing system of claim 13, wherein each of the plurality of first swing width control circuits comprises:
a first pull-up circuit configured to apply an operating voltage to the first signal transmission line in response to a first feedback signal; and
a first feedback signal generation circuit configured to output the first feedback signal in response to the first signal and a first bias applied by a first bias circuit, and wherein each of the plurality of second swing width control circuits comprises:
a second pull-up circuit configured to apply the operating voltage to the second signal transmission line in response to a second feedback signal; and
a second feedback signal generation circuit configured to output the second feedback signal in response to the second signal and a second bias applied by a second bias circuit.

17. An image sensor, comprising:
a signal transmission circuit, wherein the signal transmission circuit comprises:
a pull-down circuit configured to generate a signal in response to image data; and
a swing width control circuit coupled to an output of the pull-down circuit and configured to control a swing width of the signal to be less than a difference between an operating voltage and a ground voltage of the image sensor.

18. The image sensor of claim 17, wherein the swing width control circuit is configured to control the swing width of the signal using negative feedback.

19. The image sensor of claim 17, wherein the swing width control circuit comprises:
a feedback circuit; and
a bias circuit coupled to the feedback circuit and configured to apply a bias to the feedback circuit.

20. The image sensor of claim 19, wherein:
the signal transmission circuit further comprises a signal transmission line coupled to the pull-down circuit and the swing width control circuit; and
the feedback circuit comprises:
a pull-up circuit configured to apply the operating voltage VDD to the signal transmission line in response to a feedback signal; and
a feedback signal generation circuit configured to output the feedback signal in response to the signal and the bias applied by the bias circuit.

21. The image sensor of claim 19, wherein the feedback circuit uses negative feedback to control the swing width of the signal.

22. The image sensor of claim 17, wherein:
the pull-down circuit comprises one of a plurality of pull-down circuits; and
the swing width control circuit comprises one of a plurality of swing width control circuits arranged in an alternating sequence with the plurality of pull-down circuits.

23. The image sensor of claim 17, wherein:
the signal transmission circuit comprises a first signal transmission circuit;
the pull-down circuit comprises a first pull-down circuit configured to generate a first signal in response to the image data;
the swing width control circuit comprises a first swing width control circuit coupled to an output of the first pull-down circuit and configured to control a swing width of the first signal to be less than the difference between the operating voltage and the ground voltage; and
the signal transmission circuit further comprises a second signal transmission circuit, wherein the second signal transmission circuit comprises:
a second pull-down circuit configured to generate a second signal in response to the image data; and
a second swing width control circuit coupled to an output of the second pull-down circuit and configured to control a swing width of the second signal to be less than the difference between the operating voltage and the ground voltage.

24. The image sensor of claim 23, further comprising:
a first amplifier configured to amplify the first signal;
a second amplifier configured to amplify the second signal;
a differential amplifier configured to amplify a difference between an output signal of the first amplifier and an output signal of the second amplifier; and
a latch configured to latch an output signal of the differential amplifier in response to a clock signal.
